(19) United States
(12) Patent Application Publication
(10) Pub. No.: US 2026/0286220 A1
(43) Pub. Date: Sep. 24, 2026

(54) ETCHING SOLUTION AND ETCHING METHOD

(71) Applicant: TOKYO OHKA KOGYO CO., LTD., Kanagawa (JP)

(72) Inventor: Akira MATSUYAMA, Kanagawa (JP)

(21) Appl. No.: 19/561,846

(22) Filed: Mar. 10, 2026

Related U.S. Application Data
(60) Provisional application No. 63/775,524, filed on Mar. 21, 2025.

(51) Int. Cl. C09K 13/08; H10P 50/64

(52) U.S. Cl. CPC C09K 13/08; H10P 50/642

(57) ABSTRACT

Provided are an etching solution having high etching selectivity for silicon-germanium over SiO₂ and a method of etching a substrate using such an etching solution. The etching solution includes a fluoride ion source (A), an oxidizing agent (B), at least one nitrogen-containing organic compound (C) selected from the group consisting of a tertiary amine (C1), a tertiary amine salt (C2), and a specific nitrogen-containing organic salt (C3) each having an aliphatic hydrocarbon group that has 8 or more and 30 or less carbon atoms and is bonded to the nitrogen atom, and a solvent(S) free of any acetyloxy group-containing organic solvent.

This application is based on and claims the benefit of priority from U.S. Patent Application No. 63/775,524, filed on 21 Mar. 2025, the content of which is incorporated herein by reference.

### BACKGROUND OF THE INVENTION

### Field of the Invention

The present invention relates to an etching solution and an etching method.

### Related Art

The scaling of integrated circuit components has enabled higher densities of functional units on semiconductor chips. For example, the downscaling of transistors has enabled integration of more memory devices on chips, which leads to manufacture of higher capacity products.

Ge is a non-silicon crystalline semiconductor material used to manufacture, for example, field-effect transistors (FETs) for integrated circuit devices. In some cases, Ge has some advantageous features over silicon, such as high charge carrier (hole) mobility, small bandgap offset, different lattice constant, and the ability to form a binary semiconductor alloy (SiGe) with silicon.

Ge materials are used to make various semiconductor devices, such as gate-all-around (GAA) FETs. Gate-all-around transistors have a structure with a gate wrapping around a channel, such as a nanosheet or nanowire channel, which can facilitate the fabrication of smaller transistors with higher performance. A process of fabricating gate-all-around transistors includes forming a structure including an alternating stack of silicon and silicon-germanium layers; and selectively etching the silicon-germanium layer to remove at least part of the silicon-germanium layer.

It is disclosed that such etching is performed using an etching solution (etching composition) that is capable of selectively dissolving silicon-germanium while leaving silicon and contains an oxidizing agent (A) and an organic acid (B), wherein the oxidizing agent (A) includes nitric acid, and the etching composition has an organic acid (B) content of 50 mass % or more based on the mass of the etching composition (100 mass %) (see Patent Document 1).
Patent Document 1: Japanese Unexamined Patent Application, Publication No. 2022-94679

### SUMMARY OF THE INVENTION

Unfortunately, during the fabrication of various semiconductor devices, silicon-germanium and SiO₂ coexist on the substrate in many cases. The conventional etching solution as disclosed in Patent Document 1 is disadvantageous in that it does not have sufficient etching selectivity for silicon-germanium over SiO₂ although it has good etching selectivity for silicon-germanium over silicon. Thus, there is a need for an etching solution having high etching selectivity for silicon-germanium over SiO₂.

It is an object of the present invention, which has been made in light of the circumstances, to provide an etching solution having high etching selectivity for silicon-germanium over SiO₂ and to provide a method of etching a substrate using such an etching solution.

The inventors have created an etching solution including a fluoride ion source (A), an oxidizing agent (B), at least one Nitrogen-Containing Organic Compound (C) selected from the group consisting of a tertiary amine (C1) having an aliphatic chain hydrocarbon group that has 8 or more and 30 or less carbon atoms and is bonded to the nitrogen atom, a tertiary amine salt (C2) having an aliphatic C₈-C₃₀ chain hydrocarbon group bonded to the nitrogen atom, and a specific nitrogen-containing organic salt (C3) having an aliphatic C₈-C₃₀ chain hydrocarbon group bonded to the nitrogen atom, and a solvent (S) free of any acetyloxy group-containing organic solvent. The inventors have completed the present invention based on findings that such an etching solution can provide a solution to the problem described above. Specifically, the present invention provides the following aspects.

A first aspect of the present invention is directed to an etching solution including: a fluoride ion source (A); an oxidizing agent (B); a Nitrogen-Containing Organic Compound (C); and a solvent(S),
the Nitrogen-Containing Organic Compound (C) being one or more selected from the group consisting of a tertiary amine (C1), a tertiary amine salt (C2), and a nitrogen-containing organic salt (C3),
the tertiary amine salt (C2) being a salt of a tertiary amine and a protic acid,
the nitrogen-containing organic salt (C3) being a salt including: a nitrogen-containing cation selected from the group consisting of a quaternary ammonium cation and an N-alkyl nitrogen-containing heterocyclic cation; and an anion, the Nitrogen-Containing Organic Compound (C) having an aliphatic chain hydrocarbon group that has 8 or more and 30 or less carbon atoms and is bonded to the nitrogen atom, the solvent(S) being free of any acetyloxy group-containing organic solvent.

A second aspect of the present invention is directed to a method of etching a substrate having an etching-target surface at least partially including silicon-germanium, the method including: bringing the etching-target surface into contact with the etching solution according to the first aspect to etch the silicon-germanium.

The present invention provides an etching solution having high etching selectivity for silicon-germanium over SiO₂ and provides a method of etching a substrate using such an etching solution.

### DETAILED DESCRIPTION OF THE INVENTION

Hereinafter, specific embodiments of the present invention will be described in detail. It should be noted that the embodiments described below are not intended to limit the present invention and may be altered or modified as appropriate without departing from the gist of the present invention.

### [Etching Solution]

The etching solution includes a fluoride ion source (A), an oxidizing agent (B), a Nitrogen-Containing Organic Compound (C), and a solvent(S). The Nitrogen-Containing Organic Compound (C) is one or more selected from the group consisting of a tertiary amine (C1), a tertiary amine salt (C2), and a nitrogen-containing organic salt (C3). The tertiary amine salt (C2) is a salt of a tertiary amine and a protic acid. The nitrogen-containing organic salt (C3) is a salt including: a nitrogen-containing cation selected from the group consisting of a quaternary ammonium cation and an N-alkyl nitrogen-containing heterocyclic cation; and an anion. The Nitrogen-Containing Organic Compound (C) has an aliphatic chain hydrocarbon group that has 8 or more and 30 or less carbon atoms and is bonded to the nitrogen atom. The solvent(S) is free of any acetyloxy group-containing organic solvent. The etching solution defined above has high etching selectivity for silicon-germanium over SiO₂. Hereinafter, the essential and optional components of the etching solution will be described.

### <Fluoride Ion Source (A)>

Examples of the fluoride ion source (A) include hydrogen fluoride (HF), hexafluorosilicic acid (HFSA), hexafluorotitanic acid, hexafluorozirconic acid, tetrafluoroboric acid, tetrabutylammonium trifluoromethanesulfonate, tetraalkylammonium tetrafluoroborate (NR¹R²R³R⁴BF₄) such as tetrabutylammonium tetrafluoroborate, tetraalkylammonium hexafluorophosphate (NR¹R²R³R⁴PF₆), tetraalkylammonium fluoride (NR¹R²R³R⁴F) such as tetramethylammonium fluoride (anhydrides or hydrates thereof), ammonium bifluoride, and ammonium fluoride.

In the formulas shown above, R¹, R², R³, and R⁴ are each independently an alkyl group having 1 or more and 6 or less carbon atoms, an alkoxy group having 1 or more and 6 or less carbon atoms, an optionally-substituted aryl group, or an optionally-substituted aralkyl group. Preferred examples of the alkyl group having 1 or more and 6 or less carbon atoms include methyl, ethyl, n-propyl, isopropyl, n-butyl, isobutyl, sec-butyl, tert-butyl, n-pentyl, and n-hexyl. Preferred examples of the alkoxy group having 1 or more and 6 or less carbon atoms include methoxy, ethoxy, n-propyloxy, isopropyloxy, n-butyloxy, isobutyloxy, sec-butyloxy, tert-butyloxy, n-pentyloxy, and n-hexyloxy. Examples of the aryl group include phenyl, naphthalen-1-yl, and naphthalen-2-yl. Examples of the aralkyl group include benzyl and phenethyl. The etching solution may include a single fluoride ion source or a combination of two or more fluoride ion sources.

In particular, the fluoride ion source is preferably hydrogen fluoride and/or hexafluorosilicic acid. It should be noted that hydrogen fluoride may be used in the form of hydrofluoric acid, which is an aqueous solution of hydrogen fluoride.

The etching solution may contain the fluoride ion source (A) in any suitable amount (by mass). The etching solution preferably has a fluoride ion source (A) content of 0.001 mass % or more and 5.0 mass % or less, more preferably 0.005 mass % or more and 3.0 mass % or less, even more preferably 0.01 mass % or more and 2.0 mass % or less, based on the mass of the etching solution. With a fluoride ion source (A) content in such a range, the etching solution can easily exhibit high etching selectivity for silicon-germanium over SiO₂.

### <Oxidizing Agent (B)>

Examples of the oxidizing agent (B) include hydrogen peroxide, FeCl₃, FeF₃, Fe(NO₃)₃, Sr(NO₃)₂, COF₃, MnF₃, oxone (2KHSO₅·KHSO₄·K₂SO₄), iodic acid, vanadium (V) oxide, vanadium (IV, V) oxide, ammonium vanadate, ammonium peroxymonosulfate, ammonium chlorite, ammonium chlorate, ammonium iodate, ammonium nitrate, ammonium perborate, ammonium perchlorate, ammonium periodate, ammonium persulfate, ammonium hypochlorite, ammonium hypobromite, ammonium tungstate, sodium persulfate, sodium hypochlorite, sodium perborate, sodium hypobromite, potassium iodate, potassium permanganate, potassium persulfate, nitric acid, potassium persulfate, potassium hypochlorite, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, tetrabutylammonium peroxymonosulfate, peroxymonosulfuric acid, ferric nitrate, urea peroxide, peracetic acid, orthoperiodic acid (H₅IO₆), metaperiodic acid (HIO₄), methyl-1,4-benzoquinone (MBQ), 1,4-benzoquinone (BQ), 1,2-benzoquinone, 2,6-dichloro-1,4-benzoquinone (DCBQ), toluquinone, 2,6-dimethyl-1,4-benzoquinone (DMBQ), chloranil, alloxan, N-methylmorpholine N-oxide, and trimethylamine N-oxide. The etching solution may contain a single oxidizing agent (B) or a combination of two or more oxidizing agents (B).

In particular, the oxidizing agent (B) is preferably one or more selected from the group consisting of iodic acid, periodic acid, nitric acid, and hydrogen peroxide.

The etching solution may contain the oxidizing agent (B) in any suitable amount (by mass). The etching solution preferably has an oxidizing agent (B) content of 0.001 mass % or more and 30 mass % or less, more preferably 0.005 mass or more and 25 mass % or less, even more preferably 0.01 mass % or more and 20 mass % or less, based on the mass of the etching solution. With an oxidizing agent (B) content in such a range, the etching solution can easily exhibit high etching selectivity for silicon-germanium over SiO₂.

### <Nitrogen-Containing Organic Compound (C)>

The etching solution contains one or more selected from the group consisting of a tertiary amine (C1), a tertiary amine salt (C2), and a nitrogen-containing organic salt (C3). The tertiary amine salt (C2) is a salt of a tertiary amine and a protic acid. The nitrogen-containing organic salt (C3) is an organic salt including: a nitrogen-containing cation selected from the group consisting of a quaternary ammonium cation and an N-alkyl nitrogen-containing heterocyclic cation; and an anion.

The Nitrogen-Containing Organic Compound (C) has an aliphatic chain hydrocarbon group that has 8 or more and 30 or less carbon atoms and is bonded to the nitrogen atom. In the Nitrogen-Containing Organic Compound (C), the aliphatic chain hydrocarbon group bonded to the nitrogen atom preferably has 10 or more and 25 or less carbon atoms. When the etching solution contains the Nitrogen-Containing Organic Compound (C) having a nitrogen-bonded aliphatic chain hydrocarbon group with the number of carbon atoms in such a range, it can easily exhibit high etching selectivity for silicon-germanium over SiO₂.

In the Nitrogen-Containing Organic Compound (C), the aliphatic chain hydrocarbon group may be an aliphatic chain saturated hydrocarbon group or an aliphatic chain unsaturated hydrocarbon group having one or more unsaturated bonds. In the Nitrogen-Containing Organic Compound (C), the aliphatic chain hydrocarbon group may have a linear, branched, or cyclic structure or any combination of linear, branched, and cyclic structures. In the Nitrogen-Containing Organic Compound (C), the aliphatic chain hydrocarbon group is preferably an aliphatic linear- or branched-chain saturated hydrocarbon group, more preferably an aliphatic linear-chain saturated hydrocarbon group.

Preferred examples of the aliphatic chain hydrocarbon group having 8 or more and 30 or less carbon atoms include n-octyl, 2-ethylhexyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl, n-icosyl, n-heneicosyl, n-docosyl, n-tricosyl, n-tetracosyl, n-pentacosyl, n-hexacosyl, n-heptacosyl, n-octacosyl, n-nonacosyl, and n-triacontyl.

### [Tertiary Amine (C1)]

The tertiary amine (C1) is a compound derived from ammonia by replacing three hydrogen atoms with organic groups. Preferred examples of the tertiary amine (C1) include hexadecyldimethylamine, pentadecyldimethylamine, tetradecyldimethylamine, tridecyldimethylamine, dodecyldimethylamine, undecyldimethylamine, decyldimethylamine, nonyldimethylamine, octyldimethylamine, 2-ethylhexyldimethylamine, hexadecyldiethylamine, pentadecyldiethylamine, tetradecyldiethylamine, tridecyldiethylamine, dodecyldiethylamine, undecyldiethylamine, decyldiethylamine, nonyldiethylamine, octyldiethylamine, and 2-ethylhexyldiethylamine.

### [Tertiary Amine Salt (C2)]

The tertiary amine salt (C2) is a salt of a tertiary amine and a protic acid. Preferred examples of the tertiary amine include those listed above for the tertiary amine (C1).

Preferred examples of the protic acid include aliphatic carboxylic acids, such as formic acid, acetic acid, propionic acid, butanoic acid, and octanoic acid; aromatic carboxylic acids, such as benzoic acid and toluic acid; aromatic sulfonic acids, such as toluenesulfonic acid and benzenesulfonic acid; and hydrogen halides, such as hydrogen chloride, hydrogen bromide, and hydrogen iodide. In particular, for ease of obtaining or preparing the tertiary amine salt (C2), the aprotic acid is preferably a hydrogen halide, such as hydrogen chloride, hydrogen bromide, or hydrogen iodide, more preferably hydrogen chloride or hydrogen bromide, even more preferably hydrogen chloride.

Preferred examples of the tertiary amine salt (C2) include hydrochlorides and hydrobromides of hexadecyldimethylamine, pentadecyldimethylamine, tetradecyldimethylamine, tridecyldimethylamine, dodecyldimethylamine, undecyldimethylamine, decyldimethylamine, nonyldimethylamine, octyldimethylamine, 2-ethylhexyldimethylamine, hexadecyldiethylamine, pentadecyldiethylamine, tetradecyldiethylamine, tridecyldiethylamine, dodecyldiethylamine, undecyldiethylamine, decyldiethylamine, nonyldiethylamine, octyldiethylamine, and 2-ethylhexyldiethylamine.

### [Nitrogen-Containing Organic Salt (C3)]

The nitrogen-containing organic salt (C3) is an organic salt including: a nitrogen-containing cation selected from the group consisting of a quaternary ammonium cation and an N-alkyl nitrogen-containing heterocyclic cation; and an anion.

The nitrogen-containing organic salt (C3) typically includes a monovalent anion and a monovalent nitrogen-containing cation. The nitrogen-containing organic salt (C3) may include a divalent or polyvalent anion and two or more monovalent nitrogen-containing cations. Alternatively, the nitrogen-containing organic salt (C3) may include a divalent or polyvalent anion and a divalent or polyvalent nitrogen-containing cation. Alternatively, the nitrogen-containing organic salt (C3) may include two or more monovalent anions and a divalent or polyvalent nitrogen-containing cation. The nitrogen-containing organic salt (C3) preferably includes a monovalent anion and a monovalent nitrogen-containing cation.

In the nitrogen-containing organic salt (C3), the nitrogen-containing cation may also have a negatively-charged anionic moiety. In such a case, the nitrogen-containing organic salt (C3) may include a single ionic component simultaneously having a nitrogen-containing cationic moiety and an anionic moiety. The nitrogen-containing organic salt (C3) may consist of a nitrogen-containing cation having a negatively-charged anionic moiety. In such a case, the nitrogen-containing organic salt (C3) may be what is called a betaine compound.

Hereinafter, the quaternary ammonium cation, the N-alkyl nitrogen-containing heterocyclic cation, and the anion will be described.

### (Quaternary Ammonium Cation)

The quaternary ammonium cation includes a nitrogen atom and four organic groups bonded to the nitrogen atom. Preferred examples of the quaternary ammonium cation include hexadecyltrimethylammonium cation, pentadecyltrimethylammonium cation, tetradecyltrimethylammonium cation, tridecyltrimethylammonium cation, dodecyltrimethylammonium cation, undecyltrimethylammonium cation, decyltrimethylammonium cation, nonyltrimethylammonium cation, octyltrimethylammonium cation, 2-ethylhexyltrimethylammonium cation, hexadecyltrietylammonium cation, pentadecyltrietylammonium cation, tetradecyltrietylammonium cation, tridecyltrietylammonium cation, dodecyltrietylammonium cation, undecyltrietylammonium cation, decyltrietylammonium cation, nonyltrietylammonium cation, octyltrietylammonium cation, 2-ethylhexyltrietylammonium cation, dihexadecyldimethylammonium cation, dipentadecyldimethylammonium cation, ditetradecyldimethylammonium cation, ditridecyldimethylammonium cation, didodecyldimethylammonium cation, diundecyldimethylammonium cation, didecyldimethylammonium cation, dinonyldimethylammonium cation, dioctyldimethylammonium cation, di(2-ethylhexyl)dimethylammonium cation, dihexadecyldiethylammonium cation, dipentadecyldiethylammonium cation, ditetradecyldiethylammonium cation, ditridecyldiethylammonium cation, didodecyldiethylammonium cation, diundecyldiethylammonium cation, didecyldiethylammonium cation, dinonyldiethylammonium cation, dioctyldiethylammonium cation, and di(2-ethylhexyl) diethylammonium cation.

### (N-Alkyl Nitrogen-Containing Heterocyclic Cation)

The N-alkyl nitrogen-containing heterocyclic cation includes a nitrogen-containing heterocyclic ring having a nitrogen atom as a ring member; and an aliphatic chain hydrocarbon group that is bonded to the nitrogen atom and has 8 or more and 30 or less carbon atoms. In the N-alkyl nitrogen-containing heterocyclic cation, the nitrogen-containing heterocyclic ring may be an aromatic nitrogen-containing heterocyclic ring, an aliphatic nitrogen-containing heterocyclic ring, or a condensed ring of an aromatic nitrogen-containing heterocyclic ring and a hydrocarbon ring. In the N-alkyl nitrogen-containing heterocyclic cation, the nitrogen-containing heterocyclic ring may have a non-nitrogen heteroatom, such as oxygen or sulfur, as a ring member.

Examples of the nitrogen-containing heterocyclic ring include five-membered nitrogen-containing rings, such as pyrrolidine ring, pyrazoline ring, imidazolidine ring, [1,2,3]triazolidine ring, [1,2,4]triazolidine ring, tetrazolidine ring, pyrroline ring, pyrazoline ring, imidazoline ring, [1,2,3]triazolidine ring, [1,2,4]triazolidine ring, pyrrole ring, pyrazole ring, imidazole ring, [1,2,3]triazole ring, [1,2,4]triazole ring, and tetrazole ring; six-membered nitrogen-containing rings, such as pyridine ring, pyridazine ring, pyrimidine ring, pyrazine ring, piperidine ring, piperazine ring, and morpholine ring; and nitrogen-containing condensed rings, such as quinoline ring, isoquinoline ring, quinazoline ring, pteridine ring, indole ring, benzimidazole ring, purine ring, acridine ring, phenoxazine ring, and phenothiazine ring.

Preferred examples of the N-alkyl nitrogen-containing heterocyclic cation include N-alkylpyridinium cations, such as 1-hexadecylpyridinium cation, 1-pentadecylpyridinium cation, 1-tetradecylpyridinium cation, 1-tridecylpyridinium cation, 1-dodecylpyridinium cation, 1-undecylpyridinium cation, 1-decylpyridinium cation, 1-nonylpyridinium cation, 1-octylpyridinium cation, and 1-(2-ethylhexyl)pyridinium cation; N-alkyl-4-methylpyridinium cations, such as 1-hexadecyl-4-methylpyridinium cation, 1-pentadecyl-4-methylpyridinium cation, 1-tetradecyl-4-methylpyridinium cation, 1-tridecyl-4-methylpyridinium cation, 1-dodecyl-4-methylpyridinium cation, 1-undecyl-4-methylpyridinium cation, 1-decyl-4-methylpyridinium cation, 1-nonyl-4-methylpyridinium cation, 1-octyl-4-methylpyridinium cation, and 1-(2-ethylhexyl)-4-methylpyridinium cation; N-alkylimidazolium cations, such as 1-hexadecylimidazolium cation, 1-pentadecylimidazolium cation, 1-tetradecylimidazolium cation, 1-tridecylimidazolium cation, 1-dodecylimidazolium cation, 1-undecylimidazolium cation, 1-decylimidazolium cation, 1-nonylimidazolium cation, 1-octylimidazolium cation, and 1-(2-ethylhexyl) imidazolium cation; N-alkyl-3-methylimidazolium cations, such as 1-hexadecyl-3-methylimidazolium cation, 1-pentadecyl-3-methylimidazolium cation, 1-tetradecyl-3-methylimidazolium cation, 1-tridecyl-3-methylimidazolium cation, 1-dodecyl-3-methylimidazolium cation, 1-undecyl-3-methylimidazolium cation, 1-decyl-3-methylimidazolium cation, 1-nonyl-3-methylimidazolium cation, 1-octyl-3-methylimidazolium cation, and 1-(2-ethylhexyl)-3-methylimidazolium cation; 1-methyl-1-hexadecylpiperidinium cation, 1-methyl-1-pentadecylpiperidinium cation, 1-methyl-1-tridecylpiperidinium cation, 1-methyl-1-dodecylpiperidinium cation, 1-methyl-1-undecylpiperidinium cation, 1-methyl-1-decylpiperidinium cation, 1-methyl-1-nonylpiperidinium cation, 1-methyl-1-octylpiperidinium cation, and 1-methyl-1-(2-ethylhexyl) piperidinium cation.

### (Anion)

The nitrogen-containing organic salt (C3) includes the nitrogen-containing cation described above and an anion. The anion may be an inorganic anion or an organic anion. Preferred examples of the anion include formate ion, acetate ion, propionate ion, octanoate ion, oxalate ion, malonate ion, succinate ion, glutarate ion, adipate ion, benzoate ion, toluate ion, ethylbenzoate ion, methyl carbonate ion, toluenesulfonate ion, benzenesulfonate ion, chloride ion, bromide ion, iodide ion, OH—, SO₄²—, HSO₄—, CO₃²—, and HCO₃—.

For example, the nitrogen-containing organic salt (C3) preferably includes any one of the preferred examples of the quaternary ammonium cation or the N-alkyl nitrogen-containing heterocyclic cation and any one of the preferred examples of the anion.

The etching solution may contain the Nitrogen-Containing Organic Compound (C) in any amount that provides the desired effect. The etching solution preferably has a Nitrogen-Containing Organic Compound (C) content of 1.0 mass % or less, more preferably 0.0001 mass % or more and 1.0 mass % or less, even more preferably 0.0001 mass % or more and 0.5 mass or less, furthermore preferably 0.003 mass % or more and 0.3 mass % or less, based on the mass of the etching solution.

If an etching solution only containing the fluoride ion source (A) and the oxidizing agent (B) is brought into contact with a substrate having an exposed SiO₂ surface and an exposed silicon-germanium surface, the fluoride ion source (A) may act to dissolve SiO₂ into the etching solution. In contrast, when the etching solution containing the Nitrogen-Containing Organic Compound (C) (having the aliphatic chain hydrocarbon group that has 8 or more and 30 or less carbon atoms) in addition to the fluoride ion source (A) and the oxidizing agent (B) is brought into contact with such a substrate, the Nitrogen-Containing Organic Compound (C) can adsorb on the SiO₂ surface. As a result, the aliphatic chain hydrocarbon group having 8 or more and 30 or less carbon atoms will sterically hinder the fluoride ion source (A) from etching SiO₂.

In this regard, the Nitrogen-Containing Organic Compound (C) having the aliphatic chain hydrocarbon group that has 8 or more and 30 or less carbon atoms may adsorb on the SiO₂ surface by the following mechanism.

In general, the SiO₂ surface has a biased charge distribution. Thus, the SiO₂ surface can electrically interact with the nitrogen-containing cation having the aliphatic C₈-C₃₀ chain hydrocarbon group, derived from the tertiary amine salt (C2) or the nitrogen-containing organic salt (C3), to adsorb the nitrogen-containing cation. Moreover, the tertiary amine (C1), which has a lone electron pair (lone pair), can have a biased intramolecular charge distribution. Thus, the SiO₂ surface, which also has a biased charge distribution as mentioned above, can also electrically interact with the tertiary amine (C1) to adsorb it.

The mechanism described above will allow the Nitrogen-Containing Organic Compound (C) (at a content within the above range in the etching solution) to successfully prevent the etching of the SiO₂ surface without excessive interference with the etching of silicon-germanium. In other words, the etching solution described above has high etching selectivity for silicon-germanium over SiO₂.

### <Solvent(S)>

The etching solution contains a solvent(S) free of any acetyloxy group-containing organic solvent. Specifically, the etching solution may contain, as the solvent(S), any organic solvent other than that having a structure represented by CH₃—CO—O—R¹, and/or water. In the formula, R¹ represents an organic group.

Examples of such an organic solvent include alcohols, such as methanol, ethanol, ethylene glycol, propylene glycol, glycerin, 1,3-propanediol, 1,3-butanediol, 1,4-butanediol, diethylene glycol, dipropylene glycol, furfuryl alcohol, and 2-methyl-2,4-pentanediol; sulfoxides, such as dimethyl sulfoxide; and ethers, such as ethylene glycol dimethyl ether, diethylene glycol dimethyl ether, triethylene glycol dimethyl ether, tetraethylene glycol dimethyl ether, propylene glycol dimethyl ether, tetrahydrofuran, and 1,4-dioxane. The etching solution may contain a single solvent or a combination of two or more solvents.

### <Additional Component>

In addition to the components described above, the etching solution may contain an additional component that does not compromise the advantageous effects of the present invention. Examples of such an additional component include phosphoric acid and/or a derivative thereof, a pH adjusting agent, a passivation agent, and a surfactant.

(Phosphoric Acid and/or Derivative Thereof)

The phosphoric acid and/or a derivative thereof may be a compound represented by Formula (1) below.

O═P(OR⁰¹)₃ (1)

In Formula (1), each Rol is independently a hydrogen atom or an alkyl group having 1 or more and 20 or less carbon atoms.

Examples of the alkyl group having 1 or more and 20 or less carbon atoms for R⁰¹ in Formula (1) include methyl, ethyl, n-propyl, isopropyl, n-butyl, isobutyl, sec-butyl, tert-butyl, n-pentyl, n-hexyl, n-heptyl, 2-ethylhexyl, n-octyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl, and n-icosyl. R⁰¹ as defined above is preferably a hydrogen atom or an alkyl group having 1 or more and 10 or less carbon atoms, more preferably a hydrogen atom. The etching solution may contain phosphoric acid and/or a derivative thereof alone or two or more of phosphoric acid and derivatives thereof.

### (pH Adjusting Agent)

The pH adjusting agent is preferably at least one selected from the group consisting of: an acid not corresponding to the components described above; and a salt thereof. Examples of the pH adjusting agent include methanesulfonic acid, trifluoromethanesulfonic acid, oxalic acid dihydrate, citric acid, tartaric acid, picolinic acid, succinic acid, lactic acid, sulfosuccinic acid, benzoic acid, pyruvic acid, maleic acid, fumaric acid, malic acid, ascorbic acid, mandelic acid, heptanoic acid, butyric acid, valeric acid, glutaric acid, phthalic acid, hypophosphorous acid, salicylic acid, 5-sulfosalicylic acid, hydrochloric acid, ethanesulfonic acid, butanesulfonic acid, p-toluenesulfonic acid, dichloroacetic acid, difluoroacetic acid, monochloroacetic acid, monofluoroacetic acid, trichloroacetic acid, trifluoroacetic acid, hydrobromic acid (62 wt %), sulfuric acid, ammonium acetate, sodium acetate, potassium acetate, tetramethylammonium acetate, phosphonium acetate, ammonium butyrate, ammonium trifluoroacetate, ammonium carbonate, ammonium chloride, ammonium sulfate, phosphoric acid, diammonium hydrogen phosphate, ammonium dihydrogen phosphate, bis(tetramethylammonium) hydrogen phosphate, disodium hydrogen phosphate, sodium dihydrogen phosphate, dipotassium hydrogen phosphate, potassium dihydrogen phosphate, ditetraalkylammonium hydrogen phosphate, ditetraalkylammonium dihydrogen phosphate, diphosphonium hydrogen phosphate, phosphonium dihydrogen phosphate, ammonium phosphonate, tetramethylammonium phosphonate, sodium phosphonate, potassium phosphonate, phosphonium phosphonate, and etidronic acid, and salts of the foregoing acids. In particular, the pH adjusting agent is preferably ammonium acetate or ammonium sulfate.

The pH adjusting agent may also be a basic compound. The basic compound may be a basic organic compound or a basic inorganic compound. Examples of the basic organic compound include quaternary ammonium salts, such as quaternary ammonium hydroxides; alkylamines, such as trimethylamine and triethylamine; and salts of alkylamines. Examples of the basic inorganic compound include basic alkali metal compounds and basic alkaline-earth metal compounds. Preferred examples of the basic inorganic compound include lithium hydroxide, sodium hydroxide, potassium hydroxide, rubidium hydroxide, and cesium hydroxide. The etching solution may contain a single pH adjusting agent or a combination of two or more pH adjusting agents.

### (Passivation Agent)

Examples of the passivation agent include ascorbic acid, isoascorbic acid, ascorbic acid derivatives, boric acid, ammonium diborate, boric acid salts, amino acids, metal bromides, and ammonium bromides represented by the formula NR¹¹R¹²R¹³R¹⁴Br.

Examples of boric acid salts include ammonium pentaborate, sodium tetraborate, and ammonium diborate. Examples of amino acids include alanine, arginine, asparagine, aspartic acid, cysteine, glutamic acid, glutamine, histidine, isoleucine, leucine, lysine, methionine, phenylalanine, proline, serine, threonine, tryptophan, tyrosine, and valine. Examples of metal bromides include sodium bromide, potassium bromide, rubidium bromide, magnesium bromide, and calcium bromide.

In the formula, R¹¹, R¹², R₁₃, and R¹⁴ are each independently a hydrogen atom or an alkyl group having 1 or more and 6 or less carbon atoms. Examples of the alkyl group having 1 or more and 6 or less carbon atoms include methyl, ethyl, n-propyl, isopropyl, n-butyl, isobutyl, sec-butyl, tert-butyl, n-pentyl, and n-hexyl. The etching solution may contain a single passivation agent or a combination of two or more passivation agents.

### (Surfactant)

The etching solution may contain a surfactant for purposes such as adjusting the ability of the etching solution to wet the substrate described later. The surfactant may be one or more selected from the group consisting of a nonionic surfactant, an anionic surfactant, a cationic surfactant, and an amphoteric surfactant.

Examples of the nonionic surfactant include polyalkylene oxide alkylphenyl ether surfactants, polyalkylene oxide alkyl ether surfactants, polyethylene oxide-polypropylene oxide block polymer surfactants, polyoxyalkylene distyrenated phenyl ether surfactants, polyalkylene tribenzyl phenyl ether surfactants, and acetylene polyalkylene oxide surfactants.

Examples of the anionic surfactant include alkyl sulfonic acids, alkylbenzene sulfonic acids, alkylnaphthalene sulfonic acids, alkyl diphenyl ether sulfonic acids, fatty acid amide sulfonic acids, polyoxyethylene alkyl ether carboxylic acids, polyoxyethylene alkyl ether acetic acids, polyoxyethylene alkyl ether propionic acids, alkyl phosphonic acids, and fatty acid salts. The salts may be ammonium salts, sodium salts, potassium salts, or tetramethylammonium salts.

Examples of the cationic surfactant include quaternary ammonium salt surfactants and alkylpyridinium surfactants.

Examples of the amphoteric surfactant include betaine surfactants, amino acid surfactants, imidazoline surfactants, and amine oxide surfactants.

In general, these surfactants are commercially available. The etching solution may contain a single surfactant or a combination of two or more surfactants.

### <Method for Producing Etching Solution>

The etching solution may be produced using any suitable method. The etching solution may be produced by mixing the fluoride ion source (A), the oxidizing agent (B), the Nitrogen-Containing Organic Compound (C), the solvent(S), and any optional component.

### <<Method of Etching Substrate>>

There is provided a method of etching a substrate having an etching-target surface at least partially including SiGe, the method including: bringing the etching-target surface into contact with the etching solution described above to etch the SiGe. The etching solution has high etching selectivity for silicon-germanium over SiO₂. In a preferred mode, therefore, the etching-target surface of the substrate at least partially including SiGe should at least partially include SiO₂.

For example, the substrate having an etching-target surface at least partially including SiGe may be a semiconductor wafer, a photomask glass substrate, a liquid crystal display glass substrate, a plasma display glass substrate, a field emission display (FED) substrate, an optical disc substrate, a magnetic disc substrate, a magneto-optical disc substrate, or any other substrate. The substrate is preferably for use in semiconductor device fabrication. If necessary, the substrate may have various layers or structures, such as metal wiring, gate structures, source structures, drain structures, insulating layers, ferromagnetic layers, or non-magnetic layers.

Etching the substrate includes brining the etching-target surface into contact with the etching solution. Any suitable method may be used to bring the etching-target surface into contact with the etching solution. For example, such a method may be a spray method, an immersion method, or a puddle method.

A spray method may include spraying the etching solution on the etching-target surface to bring the etching-target surface into contact with the etching solution. If necessary, the substrate may be transported or rotated while the etching solution is sprayed on the substrate. An immersion method may include immersing the substrate in the etching solution to bring the etching-target surface into contact with the etching solution. A puddle method may include puddling the etching solution on the etching-target surface of the substrate to bring the etching-target surface into contact with the etching solution.

One of these etching methods may be appropriately selected depending on the structure, material, or any other feature of the substrate. In the spray or puddle method, the etching solution may be supplied in an amount enough to wet the etching-target surface of the substrate.

The substrate may be etched at any suitable temperature that is high enough to etch silicon-germanium at a desired rate with desired selectivity for silicon-germanium over SiO₂. For example, the substrate is preferably etched at a temperature of 15° C. or more and 70° C. or less. The etching rate increases with increasing etching solution temperature. However, minimization of changes in the composition of the etching solution, workability, safety, costs, and any other requirement should be considered when a very high temperature is selected as the temperature of the etching solution.

The substrate may be etched for any suitable period of time. The substrate may be etched until silicon-germanium is removed to the desired extent. The substrate is typically etched for a time period of 1 minute or more and 60 minutes or less.

As described above, the present invention provides aspects (1) to (5) below.
(1) An etching solution including: a fluoride ion source (A); an oxidizing agent (B); a Nitrogen-Containing Organic Compound (C); and a solvent(S),
the Nitrogen-Containing Organic Compound (C) being one or more selected from the group consisting of a tertiary amine (C1), a tertiary amine salt (C2), and a nitrogen-containing organic salt (C3),
the tertiary amine salt (C2) being a salt of a tertiary amine and a protic acid,
the nitrogen-containing organic salt (C3) being a salt including: a nitrogen-containing cation selected from the group consisting of a quaternary ammonium cation and an N-alkyl nitrogen-containing heterocyclic cation; and an anion, the Nitrogen-Containing Organic Compound (C) having an aliphatic chain hydrocarbon group that has 8 or more and 30 or less carbon atoms and is bonded to the nitrogen atom, the solvent(S) being free of any acetyloxy group-containing organic solvent.
(2) The etching solution according to aspect (1), wherein the fluoride ion source (A) is hydrogen fluoride and/or hexafluorosilicic acid.
(3) The etching solution according to aspect (1) or (2), wherein the oxidizing agent (B) is one or more selected from the group consisting of iodic acid, periodic acid, nitric acid, and hydrogen peroxide.
(4) The etching solution according to any one of aspects (1) to (3), wherein the etching solution has a Nitrogen-Containing Organic Compound (C) content of 1.0 mass % or less based on the mass of the etching solution.
(5) A method of etching a substrate having an etching-target surface at least partially including silicon-germanium, the method including: bringing the etching-target surface into contact with the etching solution according to any one of aspects (1) to (4) to etch the silicon-germanium.

### EXAMPLES

Hereinafter, the present invention will be described in more detail with reference to examples and comparative examples. It will be understood that the examples and comparative examples are not intended to limit the present invention at all.

### Examples 1 to 14 and Comparative Examples 1 to 9

### <Preparation of Etching Solutions>

As shown in Table 1, a fluoride ion source (A), an oxidizing agent (B), a Nitrogen-Containing Organic Compound (C) or an analog (C′) thereof, and a solvent(S) were mixed to form an etching solution according to each of the examples and comparative examples. The type and amount (mass %) of each component for each etching solution are shown in Table 1. The analog (C′) is a compound similar to, but not the same as, the Nitrogen-Containing Organic Compound (C).

TABLE 1

| | | | | | Nitrogen containing | | | |
|---|---|---|---|---|---|---|---|---|
| | Fluoride ion source | | Oxidizing agent | | organic compound (C) or | | Solvent | |
| | (A) | | (B) | | analog (C) | | (S) | |
| | Type | Parts by mass | Type | Parts by mass | Type | Parts by mass | Type | Parts by mass |
| Example 1 | HF | 0.2 | HIO₃ | 1 | A | 0.003 | Water | 98.797 |
| Example 2 | HFSA | 3 | HIO₃ | 1 | A | 0.003 | Water | 95.997 |
| Example 3 | HF | 0.2 | H₅IO₆ | 5 | A | 0.003 | Water | 94.797 |
| Example 4 | HF | 0.2 | HNO₃ | 20 | A | 0.003 | Water | 79.797 |
| Example 5 | HF | 0.2 | H₂O₂ | 10 | A | 0.003 | Water | 89.797 |
| Example 6 | HF | 0.2 | HIO₃ | 1 | B | 0.003 | Water | 98.797 |
| Example 7 | HF | 0.2 | HIO₃ | 1 | C | 0.003 | Water | 98.797 |
| Example 8 | HF | 0.2 | HIO₃ | 1 | D | 0.003 | Water | 98.797 |
| Example 9 | HF | 0.2 | HIO₃ | 1 | E | 0.003 | Water | 98.797 |
| Example 10 | HF | 0.2 | HIO₃ | 1 | F | 0.003 | Water | 98.797 |
| Example 11 | HF | 0.2 | HIO₃ | 1 | G | 0.003 | Water | 98.797 |
| Example 12 | HF | 0.2 | HIO₃ | 1 | H | 0.003 | Water | 98.797 |
| Example 13 | HF | 0.2 | HIO₃ | 1 | A | 0.1 | Water | 98.7 |
| Example 14 | HF | 0.2 | HIO₃ | 1 | A | 0.0001 | Water | 98.7999 |
| Comparative | HF | 0.2 | HIO₃ | 1 | — | — | Water | 98.8 |
| Example 1 | | | | | | | | |
| Comparative | HFSA | 3 | HIO₃ | 1 | — | — | Water | 96 |
| Example 2 | | | | | | | | |
| Comparative | HF | 0.2 | H₅IO₆ | 5 | — | — | Water | 94.8 |
| Example 3 | | | | | | | | |
| Comparative | HF | 0.2 | HNO₃ | 20 | — | — | Water | 79.8 |
| Example 4 | | | | | | | | |
| Comparative | HF | 0.2 | H₂O₂ | 10 | — | — | Water | 89.8 |
| Example 5 | | | | | | | | |
| Comparative | HF | 0.2 | HIO₃ | 1 | I | 0.003 | Water | 98.797 |
| Example 6 | | | | | | | | |
| Comparative | HF | 0.2 | HIO₃ | 1 | J | 0.003 | Water | 98.797 |
| Example 7 | | | | | | | | |
| Comparative | HF | 0.2 | HIO₃ | 1 | A | 0.003 | AcOEt/ | 30/ |
| Example 8 | | | | | | | Water | 68.0797 |
| Comparative | HF | 0.2 | HIO₃ | 1 | K | 0.003 | Water | 98.797 |
| Example 9 | | | | | | | | |

The following fluoride ion source (A), oxidizing agent (B), Nitrogen-Containing Organic Compound (C) or analog (C′), and solvent(S) were used as shown in Table 1.

### Fluoride Ion Source (A).

HF: Hydrofluoric acid
HFSA: Hexafluorosilicic acid

### Oxidizing Agent (B)·

HIO₃: Iodic acid.
H₅IO₆: Orthoperiodic acid
HNO₃: Nitric acid H₂O₂: Hydrogen peroxide

### Nitrogen-Containing Organic Compound (C) or Analog (C′)

A: Hexadecyltrimethylammonium hydrogen sulfate
B: Decyltrimethylammonium chloride
C: Dodecyltrimethylammonium chloride
D: Didodecyldimethylammonium bromide
E: 1-Hexadecyl-4-methylpyridinium chloride
F: 1-Hexadecyl-3-methylimidazolium chloride
G: 1-Dodecyl-3-methylimidazolium chloride
H: N, N-Dimethylhexadecylamine
I: Hexadecylamine
J: Trihexyl(tetradecyl)phosphonium chloride
K: Trimethylpropylammonium bromide
Solvent(S)
AcOEt: Ethyl acetate

### <Method for Measuring Silicon-Germanium (SiGe) Etching Rate>

A blanket substrate having a surface SiGe layer was immersed in hydrofluoric acid (HF:water=100:1 (mass ratio)) for the removal of the oxide film from the substrate surface. The substrate was then washed with deionized water (DIW). The washed substrate was dried under a nitrogen stream. The dried substrate was etched by being immersed in the etching solution shown in Table 1 at 25° C. for 1 minute. After the immersion, the substrate was washed with deionized water (DIW). The washed substrate was dried under a nitrogen stream.

X-ray fluorescence (XRF) analysis was performed to measure the thickness of the surface SiGe layer before the immersion of the substrate in hydrofluoric acid and after the immersion, water-washing, and drying of the substrate. The difference between the measured thicknesses and the time period of immersion in the etching solution were used to calculate the SiGe etching rate ((the thickness difference (nm))/(the time period (minutes) of immersion in the etching solution)). The results are shown in the “SiGe” column of Table 2.

### <Method for Measuring Silicon Oxide (SiO₂) Etching Rate>

A blanket substrate having a surface SiO₂ film was etched by being immersed in the etching solution shown in Table 1 at 25° C. for 5 minutes. After the immersion, the substrate was washed with deionized water (DIW). The washed substrate was dried under a nitrogen stream.

A spectroscopic ellipsometer was used to measure the thickness of the surface SiO₂ film before the immersion of the substrate in the etching solution and after the immersion, water-washing, and drying of the substrate. The difference between the measured thicknesses and the time period of immersion in the etching solution were used to calculate the SiO₂ etching rate ((the thickness difference (nm))/the time period (minutes) of immersion in the etching solution)). The results are shown in Table 2.

Table 2 shows the etching selectivity ((the SiGe etching rate)/(the SiO₂ etching rate)) calculated from the SiGe etching rate and the SiO₂ etching rate.

TABLE 2

| | Etching rate | | Etching |
|---|---|---|---|
| | [nm/minutes] | | selectivity |
| | SiGe | SiO₂ | SiGe/SiO₂ |
| Example 1 | 9.8 | 0.05 | 194 |
| Example 2 | 5.9 | 0.02 | 293 |
| Example 3 | 3.0 | 0.08 | 38 |
| Example 4 | 26.0 | 0.18 | 144 |
| Example 5 | 10.2 | 0.28 | 37 |
| Example 6 | 9.6 | 0.32 | 30 |
| Example 7 | 8.2 | 0.14 | 58 |
| Example 8 | 9.8 | 0.18 | 54 |
| Example 9 | 8.9 | 0.01 | 766 |
| Example 10 | 7.6 | 0.01 | 509 |
| Example 11 | 7.1 | 0.11 | 62 |
| Example 12 | 3.7 | 0.11 | 34 |
| Example 13 | 6.2 | 0.01 | 623 |
| Example 14 | 10.2 | 0.22 | 47 |
| Comparative Example 1 | 10.4 | 0.59 | 18 |
| Comparative Example 2 | 6.0 | 0.28 | 21 |
| Comparative Example 3 | 6.1 | 1.32 | 5 |
| Comparative Example 4 | 36.4 | 1.74 | 21 |
| Comparative Example 5 | 15.7 | 2.24 | 7 |
| Comparative Example 6 | 10.8 | 0.59 | 18 |
| Comparative Example 7 | 10.9 | 0.56 | 19 |
| Comparative Example 8 | 1.7 | 1.22 | 1.4 |
| Comparative Example 9 | 10.2 | 0.61 | 17 |

Table 2 shows that the etching solutions of Examples 1 to 14, which contain the fluoride ion source (A), the oxidizing agent (B), the Nitrogen-Containing Organic Compound (C) satisfying the specified conditions, and the solvent(S) free of any acetyloxy group-containing organic solvent, have high etching selectivity for silicon-germanium over SiO₂ as compared to those of Comparative Examples 1 to 9.

What is claimed is:

1. An etching solution comprising:
a fluoride ion source (A); an oxidizing agent (B); a nitrogen-containing organic compound (C); and a solvent(S),
the nitrogen-containing organic compound (C) being one or more selected from the group consisting of a tertiary amine (C1), a tertiary amine salt (C2), and a nitrogen-containing organic salt (C3),
the tertiary amine salt (C2) being a salt of a tertiary amine and a protic acid,
the nitrogen-containing organic salt (C3) being a salt comprising: a nitrogen-containing cation selected from the group consisting of a quaternary ammonium cation and an N-alkyl nitrogen-containing heterocyclic cation; and an anion,
the nitrogen-containing organic compound (C) having an aliphatic chain hydrocarbon group that has 8 or more and 30 or less carbon atoms and is bonded to a nitrogen atom,
the solvent(S) being free of any acetyloxy group-containing organic solvent.

2. The etching solution according to claim 1, wherein the fluoride ion source (A) is hydrogen fluoride and/or hexafluorosilicic acid.

3. The etching solution according to claim 1, wherein the oxidizing agent (B) is one or more selected from the group consisting of iodic acid, periodic acid, nitric acid, and hydrogen peroxide.

4. The etching solution according to claim 1, wherein the etching solution has a nitrogen-containing organic compound (C) content of 1.0 mass % or less based on the mass of the etching solution.

5. A method of etching a substrate having an etching-target surface at least partially comprising silicon-germanium, the method comprising: bringing the etching-target surface into contact with the etching solution according to claim 1 to etch the silicon-germanium.
